(19) United States
(12) Patent Application Publication
(10) Pub. No.: US 2005/0263752 A1
(43) Pub. Date: Dec. 1, 2005

(54) Thermoelectric material with integrated de broglie wave filter

(76) Inventors: Avto Tavkhelidze, Tbilisi (GE); Leri Tsakadze, Tbilisi (GE)

Correspondence Address: Borealis Technical Limited, 23545 NW Skyline Blvd, North Plains, OR, 97133-9204, US

(21) Appl. No.: 10/531,367

(22) PCT Filed: Oct. 20, 2003
(86) PCT No.: PCT/IB03/06480

§ 371 Date: Apr. 13, 2005

(30) Foreign Application Priority Data
Oct. 20, 2002 (GB) 0224300.4

(51) Int. Cl. H01L 29/06; H01L 31/072

(52) U.S. Cl. 257/17; 257/10; 257/30; 257/14

(57) ABSTRACT

In this invention we offer a method which blocks movement of low energy electrons through the thermoelectric material. We achieve this using filter which is more transparent for high energy electrons than for low energy ones. Tunnel barrier on the way of the electrons is used as filter. Filter works on the basis of the wave properties of the electrons. The geometry of the tunnel barrier is such that barrier becomes transparent for electrons having certain de Broglie wavelength. If the geometry of the barrier is such that its transparency wavelength matches the wavelength of high energy electrons it will be transparent for high energy electrons and will be blocking low energy ones by means of tunnel barrier.

### TECHNICAL FIELD

The present invention relates to thermoelectric materials.

### BACKGROUND ART

Up to date thermoelectric generators and refrigerators have low efficiency. One of the main reasons for this low efficiency is that all free electrons around and above the Fermi level take part in current transport through the thermoelectric material, but it is only high energy electrons that are efficiently used for cooling and energy generation.

FIG. 1 shows a simple diagrammatic representation of a thermoelectric couple known in the art in which a p-type material is connected to an n-type material via a conducting bridge, and electrons flow through the device, pumping heat from one side of the couple to the other. Other configurations and combinations of materials are also used. As mentioned already, the low efficiency of such arrangements arises from the fact that all the free electrons around and above the Fermi level take part in current transport through the thermoelectric material and consequently external current source makes work which is not efficiently used for heat transfer.

In U.S. Pat. No. 6,281,514 a method for promoting the passage of electrons through a potential barrier comprising providing a potential barrier having a geometrical shape for causing de Broglie interference is disclosed. This results in the increase of tunneling through the potential barrier.

This approach does not contemplate using such a potential barrier for controlling or filtering which electrons contribute to current transport through the thermoelectric materials.

FIG. 2 shows two domains are separated by a surface 36 having an indented or protruded shape, with height a.

An incident probability wave 30 is reflected from surface 36 to give reflected probability wave 32, and from the bottom of the indent to give reflected probability wave will equal to zero for waves having wavelength λ=4a/ (1+2n) where n=0, 1, 2 . . . . Further this means that the electron will not reflect back from the border, and will leak through the potential barrier with increased probability.

Indents or protrusions on the surface should have dimensions comparable to de Broglie wavelength of electron. In particular indent or protrusion height should be
a=λ(1+2n)/4

And the indent or protrusion width should be much grater than λ.

In this invention we offer a method which blocks movement of low energy electrons through the thermoelectric material. We achieve this using filter which is more transparent for high energy electrons than for low energy ones. Tunnel barrier on the way of the electrons is used as filter. Filter works on the basis of the wave properties of the electrons. The geometry of the tunnel barrier is such that barrier becomes transparent for electrons having certain de Broglie wavelength. If the geometry of the barrier is such that its transparency wavelength matches the wavelength of high energy electrons it will be transparent for high energy electrons and will be blocking low energy ones by means of tunnel barrier.

### DISCLOSURE OF INVENTION

In one aspect, the present invention comprises a method for filtering electrons, allowing the most energetic ones to travel freely through a thermoelectric material whilst at the same time blocking low energy electrons and preventing them from taking part in current transport. This is achieved by creating a tunnel barrier or filter on the ‘anode’ surface of a thermoelectric material having a geometric pattern comprising indentations or protrusions. The dimensions of the indents or protrusions are such that electrons below a certain energy are reflected by the tunnel barrier or filter, whilst electrons above a certain energy are able to pass through the tunnel barrier or filter. Specifically, the depth of the indents or height of protrusions is λ(1+2n)/4, where λ is the de Broglie wavelength of an electron having the fore-mentioned certain energy.

In a second aspect, the present invention comprises a thermoelectric material having a tunnel barrier or filter on its ‘anode’ surface, in which the tunnel barrier or filter has a geometric pattern comprising indentations or protrusions. The dimensions of the indents or protrusions are such that electrons below a certain energy are reflected by the tunnel barrier or filter, whilst electrons above a certain energy are able to pass through the tunnel barrier or filter. Specifically, the dimensions of the indents or protrusions are λ(1+2n)/4, where λ is the de Broglie wavelength of an electron having the fore-mentioned certain energy.

In a further aspect, the present invention comprises a thermoelectric device comprising a first thermoelectric material and a second thermoelectric material, and having a tunnel barrier or filter interposed between the first material and the second material, in which the tunnel barrier or filter has a geometric pattern comprising indentations or protrusions. The dimensions of the indents or protrusions are such that electrons below a certain energy are reflected by the tunnel barrier or filter, whilst electrons above a certain energy are able to pass through the tunnel barrier or filter. Specifically, the dimensions of the indents or protrusions are λ(1+2n)/4, where λ is the de Broglie wavelength of an electron having the fore-mentioned certain energy.

In a yet further aspect, the present invention comprises a thermoelectric device comprising a first thermoelectric material, a second thermoelectric material, and one or more tunnel barriers or filters, in which the tunnel barriers or filters have a geometric pattern comprising indentations or protrusions. The dimensions of the indents or protrusions are such that electrons below a certain energy are reflected by the tunnel barriers or filters, whilst electrons above a certain energy are able to pass through the tunnel barriers or filters. Specifically, the dimensions of the indents or protrusions are λ(1+2n)/4, where λ is the de Broglie wavelength of an electron having the fore-mentioned certain energy.

### BRIEF DESCRIPTION OF DRAWINGS

FIG. 1 shows in diagrammatic form, a typical prior art thermoelectric device;

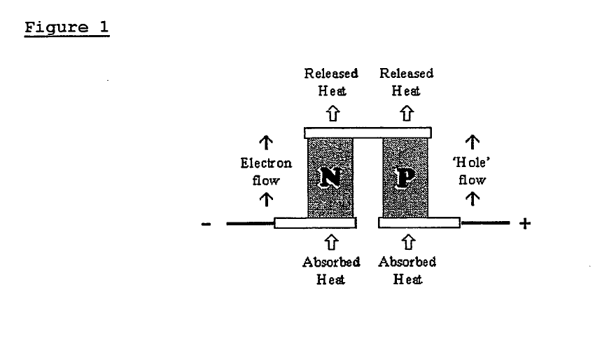

FIG. 2 shows in diagrammatic form, an incident probability wave, two reflected probability waves and a transmitted probability wave interacting with a surface having a series of indents (or protrusions);

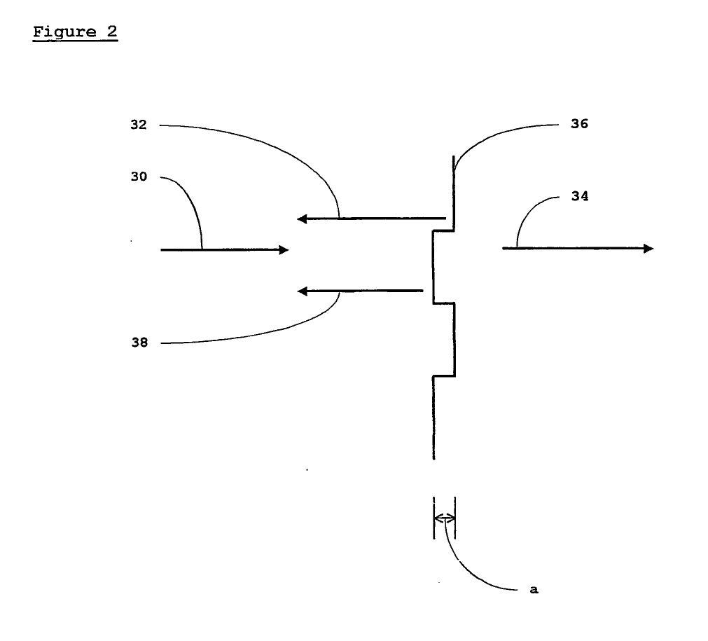

FIG. 3 shows in a diagrammatic form a tunnel barrier or filter of the present invention;

FIG. 4 shoes in diagrammatic form several configurations for thermoelectric devices of the present invention.

### BEST MODE FOR CARRYING OUT THE INVENTION

In the following, reference is made to indented and protruded cross-sections, geometries and surfaces. It is to be understood that for the purpose of the present invention that these terms are considered to be equivalent, and, for example, that the height of a protrusion is equivalent to the depth of an indent.

The present invention concerns the use of tunnel barriers or filters for controlling current transport in thermoelectric materials and devices. The tunnel barriers or filters have a stepped geometry comprising indents or protrusions in which the depth of the steps is such that high-energy electrons cannot reflect back from the step-like structure because of interference of de Broglie waves. Consequently high-energy electrons have to tunnel through the barrier. Low energy electrons have longer wavelengths and they can reflect-back from the step-like structure. Thus the tunnel barrier partially stops low energy electrons and is more transparent for high-energy electrons because of wave nature of the electron. The effect of introducing an indented or protruded surface in this way is that the tunnel barrier stops low energy electrons and is transparent for high energy ones.

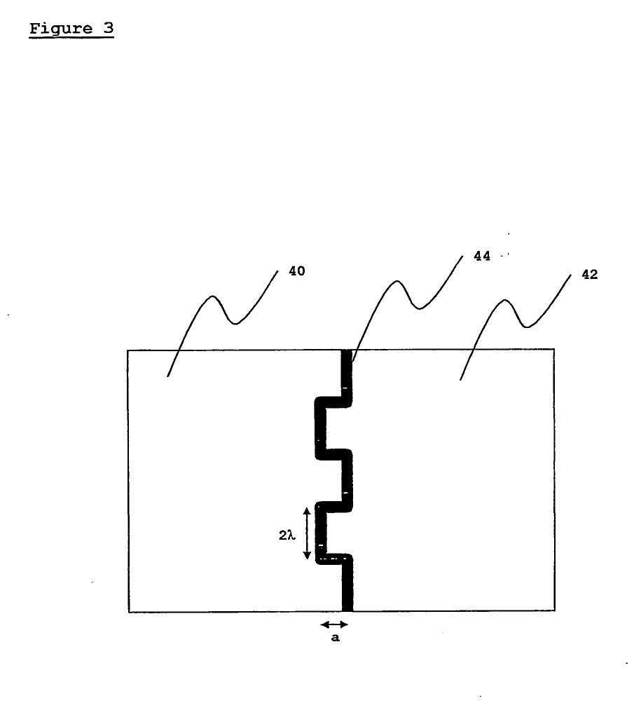

Referring now to FIG. 3, which depicts one embodiment for a tunnel barrier of the present invention, two materials 40 and 42 are separated by the thin electrical insulator material 44. The insulator material can be any one of a number of materials such as SiO₂, Si₃N₄, Al₂O₃ or titanium oxide. Materials 40 and 42 may be the same or different, and may be either semiconductors or metals. A variety of suitable semiconductors are known and include Bi₂Te₃ and its Sb— and Se— doped phases, Bi₁₋ₓSbₓ, and CoSb. The interface 46 between materials 40 and 42 is indented/protruded as shown. The depth of the indentations at this interface are a, and the width is much more than λ, where λ is the de Broglie wavelength. Typically a is in the range of 10-100λ. The value for a is chosen to set a threshold energy value above which the barrier is transparent to electron flow, and below which electron flow is prevented.

The insulating layer may be formed by a number of means known to the art including including sputter deposition, vacuum evaporation, chemical vapor deposition (CVD), electrochemical deposition. Thus deposition of the insulating layers such as SiO2, Si3N4, Al2O3 etc., may be achieved using thermal evaporation or sputtering methods, or the growth of native oxides.

The films are synthesized by pulsed laser deposition where the crystallinity can be controlled by the deposition temperature.

In a preferred embodiment, an indented/protruded structure is formed on the surface of material 40. This may be achieved by a number of methods known to the art, as disclosed above and may also include pulsed laser deposition where the crystallinity can be controlled by the deposition temperature. In a second step, insulating material 44 is deposited over the indented/protruded surface so formed or grown as insulating oxide of 40. In a third step, material 42 is attached to the indented/protruded surface so formed. Again, this may be achieved by a number of methods known to the art, including deposition and electrochemical growth.

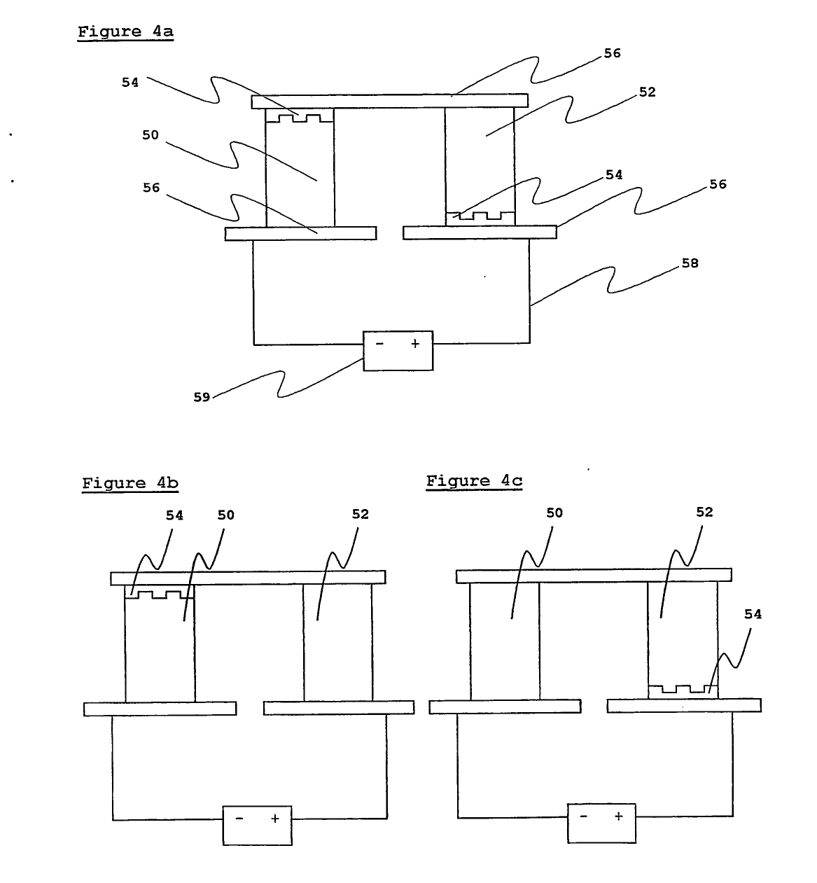

Thermoelectric devices comprising the barrier are also contemplated. FIG. 4 shows several thermoelectric devices of the present invention having an n-type material 50, a p-type material 52, conductors 56 and an external circuit 58 and power source 59. A barrier or filter 54 is in electrical contact with the ‘anode’ end of the p-type and n-type materials, and is also in electrical contact with a conductor. FIG. 4a shows a device having two barriers or filters, FIG. 4b shows a device having a barrier or filter attached to the anode end of the n-type material, and FIG. 4c shows a device having a barrier or filter attached to the anode end of the p-type material.

### INDUSTRIAL APPLICABILITY

The tunnel barrier of the present invention may be utilized in a number of thermoelectric devices for improving the their efficiency. For example the use of the tunnel barrier will increase the cooling capacity of Peltier devices, as well as improving the generation of electricity by thermoelectric generators.

1: A tunnel barrier for controlling the movement of electrons through a thermoelectric material comprising a potential barrier having an indented or protruded cross-section.

2: The tunnel barrier of claim 1 wherein the depth of indents in said indented cross-section or the height of protrusions in said protruded cross-section is chosen to set a threshold energy value above which the barrier is transparent to electron flow, and below which electron flow is prevented.

3: The tunnel barrier of claim 1 wherein the depth of indents in said indented cross-section or the height of protrusions in said protruded cross-section is given by the relationship λ(1+2n)/4, where λ is the de Broglie wavelength of said electrons, and where n is 0 or a positive integer.

4: The tunnel barrier of claim 3 in which n is an integer having a value between 0 and 4.

5: The tunnel barrier of claim 1 wherein the width of indents in said indented cross-section or the width of protrusions in said protruded cross-section the width is much more than λ, where λ is the de Broglie wavelength.

6: The tunnel barrier of claim 1 in which said potential barrier comprises an electrical insulator.

7: A thermoelectric device comprising:
a) a first thermoelectric material;
b) a second thermoelectric material;
c) one or more tunnel barriers of claim 1.

8: The thermoelectric device of claim 7 wherein said first thermoelectric material comprises an n-type material, said second thermoelectric material comprises a p-type material, and wherein a tunnel barrier of claim 1 is in electrical contact with an anode of said n-type material and a cathode of said p-type material.

9: The thermoelectric device of claim 7 wherein said first thermoelectric material comprises an n-type material, said second thermoelectric material comprises a p-type material in electrical contact with said n-type material, and wherein a tunnel barrier of claim 1 is in electrical contact with an anode of said p-type material.

10: The thermoelectric device of claim 7 wherein said first thermoelectric material comprises an n-type material, said second thermoelectric material comprises a p-type material, and wherein a tunnel barrier of claim 1 is in electrical contact with a anode of said n-type material and a further tunnel barrier of claim 1 is in electrical contact with an anode of said p-type material.

11: A method for making the thermoelectric device of claim 7 comprising:
(a) forming an indented or protruded structure on a surface of a first thermoelectric material;
(b) forming an electrically insulating material over said indented or protruded surface;
(c) attaching a second thermoelectric material to said insulating material.

12: The method of claim 11 in which said step of forming an insulating material comprises depositing said insulating material.

13: The method of claim 11 in which said step of forming an insulating material comprises oxidising said first material.

14: The method of claim 11 in which said step of forming an indented or protruded structure comprises etching.

15: The method of claim 11 in which said step of forming an indented or protruded structure comprises ablation.

16: The tunnel barrier of claim 1 wherein the depth of indents in said indented cross-section or the height of protrusions in said protruded cross-section is in the range 10-100λ, where λ is the de Broglie wavelength of said electrons.

17: The tunnel barrier of claim 6 in which said electrical insulator is selected from the group consisting of: SiO₂, Si₃N₄, Al₂O₃ and titanium oxide.

18: The thermoelectric device of claim 7 in which said first or said second thermoelectric material is selected from the group consisting of: Bi₂Te₃, Sb-doped Bi₂Te₃, Se-doped Bi₂Te₃, Bi₁₋ₓSbₓ, and CoSb.

19: The method of claim 11 in which said insulator material is selected from the group consisting of: SiO₂, Si₃N₄, Al₂O₃ and titanium oxide.

20: The method of claim 11 in which said first or said second thermoelectric material is selected from the group consisting of: Bi₂Te₃, Sb-doped Bi₂Te₃, Se-doped Bi₂Te₃, Bi₁₋ₓSbₓ, and CoSb.
